(19) United States
(12) Patent Application Publication
(10) Pub. No.: US 2008/0016425 A1
(43) Pub. Date: Jan. 17, 2008

(54) TURBO DECODER WITH SYMMETRIC AND NON-SYMMETRIC DECODING RATES

(75) Inventors: Safi Ullah Khan, San Diego, CA (US); Thomas Sun, San Diego, CA (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 11/696,118

(22) Filed: Apr. 3, 2007

Related U.S. Application Data
(60) Provisional application No. 60/789,457, filed on Apr. 4, 2006.

(51) Int. Cl. H03M 13/00

(52) U.S. Cl. 714/755

(57) ABSTRACT

A receiver includes a turbo decoder, and a depuncture module configured to enable the turbo decoder to selectively operate at a symmetric code rate and an asymmetric code rate.

### CLAIM OF PRIORITY UNDER 35 U.S.C. §119

The present Application for Patent claims priority to Provisional Application No. 60/789,457 entitled “⅔ Rate Turbo Decoder” filed Apr. 4, 2006, and assigned to the assignee hereof and hereby expressly incorporated by reference herein.

### FIELD

The present disclosure relates generally to telecommunication systems, and more particularly, to concepts and techniques for turbo decoding using symmetric and non-symmetric decoding rates.

### BACKGROUND

Reliable communications at high spectral efficiency is achieved with the use of multi-level modulation schemes together with powerful coding techniques. These coding techniques provide redundancy that the receiver may use to correct errors.

In a typical telecommunications system, a code segment or data packet is encoded with a turbo code before transmission. The turbo encoding process produces several “code symbols” for each “bit” of data in the code segment. The code symbols include “systematic symbols” and “parity symbols.” The systematic symbols represent the data in the code segment, and the parity symbols provide the redundancy. The “code rate” is the measure of redundancy introduced by the turbo encoder (i.e., the number of systematic symbols divided the number of total symbols in the code segment). The code rate is generally referred to as either symmetric or asymmetric. A “symmetric code rate” is one in which the number of parity symbols is an integer multiple of the number of systematic symbols in the code segment. Examples of symmetric code rates include ½, ⅓, and ⅕. When the number of parity symbols is not an integer multiple of the number of systematic symbols, the code rate is said to be asymmetric, such as the case with a ⅔ code rate.

The code symbols produced by the turbo encoder are typically blocked together and mapped to points on a signal constellation, thereby producing a sequence of “modulation symbols.” This sequence may be provided to an analog front end (AFE), which generates a continuous time signal, which is transmitted over a communications channel.

Because of noise and other disturbances in the communications channel, the modulation symbols recovered by the receiver may not correspond to the exact location of a point in the original signal constellation. A symbol demapper may be used to make “soft decisions” as to which modulation symbols were most likely transmitted based on the received points in the signal constellation. The soft decisions may be used to extract log-likelihood ratio (LLR) values for the code symbols. A turbo decoder uses the code symbol LLR values to decode the data that was originally transmitted.

The turbo decoder is generally designed to minimize the latency inherent in the decoding process to support real-time applications such as voice communications. For this reason, turbo decoders are conventionally made using hard-wired state machine logic. While state machine logic is fast, it is not flexible, and it is difficult to make use of the same hardware elements to enable a receiver to decode multiple coding rates. This difficulty has not been overcome when attempting to use hardware designed for symmetric code rates to support asymmetric code rates. Accordingly, there is a need in the art for a turbo decoder that can efficiently support both symmetric and asymmetric code rates.

### SUMMARY

In accordance with one aspect of the disclosure, a receiver includes a turbo decoder, and a depuncture module configured to enable the turbo decoder to selectively operate at a symmetric code rate and an asymmetric code rate.

In accordance with another aspect of the disclosure, a receiver includes a turbo decoder, and means for enabling the turbo decoder to selectively operate at a symmetric code rate and an asymmetric code rate.

In accordance with yet another aspect of the disclosure, a method of communications using a turbo decoder capable of operating at a symmetric code rate includes depuncturing LLR values for code symbols to enable the turbo decoder to operate at an asymmetric code rate, and using the depunctured LLR values to operate the turbo decoder at the asymmetric code rate.

### BRIEF DESCRIPTION OF THE DRAWINGS

FIG. 1 is a schematic block diagram illustrating an example of a transmitter and receiver in a telecommunications system;

FIG. 2 is a schematic block diagram illustrating an example of a turbo encoder;

FIG. 3 is a schematic block diagram of the turbo encoder in FIG. 2 in greater detail;

FIG. 4 is a schematic block diagram illustrating a portion of the receiver in FIG. 1 with the turbo decoder shown in greater detail;

FIG. 5 is a conceptual diagram illustrating an example of a depuncture module in a receiver;

FIG. 6 is a schematic block diagram illustrating an example of a hardware implementation of a depuncture module in a receiver;

FIG. 7 is a functional block diagram illustrating a portion of the receiver in FIG. 1; and

FIG. 8 is a flow diagram illustrating an example of a method of communications using a turbo decoder capable of operating at symmetric and asymmetric code rate.

### DETAILED DESCRIPTION

Various embodiments are now described with reference to the drawings. In the following description, for purposes of explanation, numerous specific details are set forth in order to provide a thorough understanding of one or more aspects of the present invention. It may be evident, however, that such aspects may be practiced without these specific details. In other instances, well-known structures and devices are shown in block diagram form in order to facilitate describing these embodiments.

As used in this application, the terms “component,” “module,” “system,” and the like are intended to refer to a computer-related entity, either hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

Various aspects of the present invention will be presented in terms of systems that may include a number of components, modules, and the like. It is to be understood and appreciated that the various systems may include additional components, modules, etc. and/or may not include all of the components, modules etc. discussed in connection with the figures. A combination of these approaches may also be used.

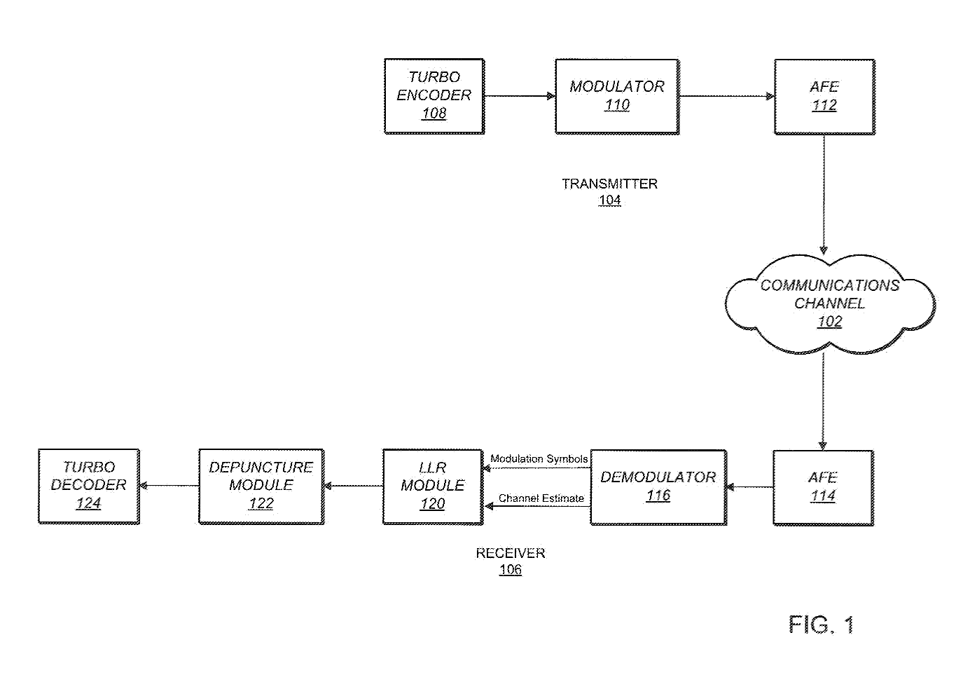

FIG. 1 is a conceptual block diagram illustrating an example of a transmitter and receiver connected by a communications channel. The communications channel 102 may be any combination of wired and wireless links. By way of example, the communications channel 102 may include any combination of cellular networks, wireless local area networks (WLANs), or other radio access networks, connected together through a wide area network (WAN), such as the Internet or a public switched telephone network (PSTN). Alternatively, or in addition to, the communications channel 102 may include an Ethernet, Digital Subscriber Lines (DSL), cable modem, fiber optic, standard telephone lines, or like the like, connected together through a WAN. In some configurations, the communications channel 102 may be a dedicated channel, such as the case be in some multicast and broadcast systems.

The transmitter 104 and receiver 106 may be any devices that are capable of supporting telephony, video, packet data, messaging, and/or other type of communications. The transmitter 104 and receiver 106 may be stand-alone entities, or integrated into telecommunications equipment. As an example of the latter, the transmitter 104 may be integrated into a base transceiver station (BTS) in a cellular or radio access network, a transmitter station in a multicast or broadcast network, an Internet Service Provider (ISP), or some other telecommunications entity. The receiver 106 may be integrated into a wireless or cellular telephone, personal digital assistant (PDA), computer, or some other suitable access terminal. Alternatively, the transmitter 104 may be integrated into the access terminal and the receiver 106 integrated into the BTS, ISP, or other similar entity.

At the transmitter104, a Turbo encoder 108 applies an iterative coding process to data and tail bits. The coding process results in a sequence of code symbols with redundancy that the receiver 106 may use to correct errors. The code symbols are provided to a modulator 110 where they are blocked together and mapped to coordinates on a signal constellation. The coordinates of each point in the signal constellation represents the baseband quadrature components that are used by an analog front end (AFE) 112 to modulate quadrature carrier signals before transmission over the communications channel 102.

An AFE 114 in the receiver 106 may be used to convert the quadrature carrier signals to their baseband components. A demodulator 116 translates the baseband components back to their correct points in the signal constellation. Because of noise and other disturbances in the channel 102, the baseband components may not correspond to valid locations in the original signal constellation. The demodulator 116 detects which modulation symbols were most likely transmitted by correcting the received points in the signal constellation based on an estimate of the channel conditions and selects valid symbols in the signal constellation which are closest to the corrected received points. These selections are referred to as “soft decisions.” Each soft decision represents an estimate of a modulation symbol that was transmitted over the communications channel 102. The soft decisions and channel estimate is used by a LLR module 120 to extract the LLR values for the code symbols associated with that modulation symbol. A turbo decoder 124 uses the sequence of code symbol LLR values to decode the data that was originally transmitted. In a manner to be described in greater detail later, a depuncture module 122 between the LLR module 120 and the turbo decoder 124 may be used to support multiple code rates.

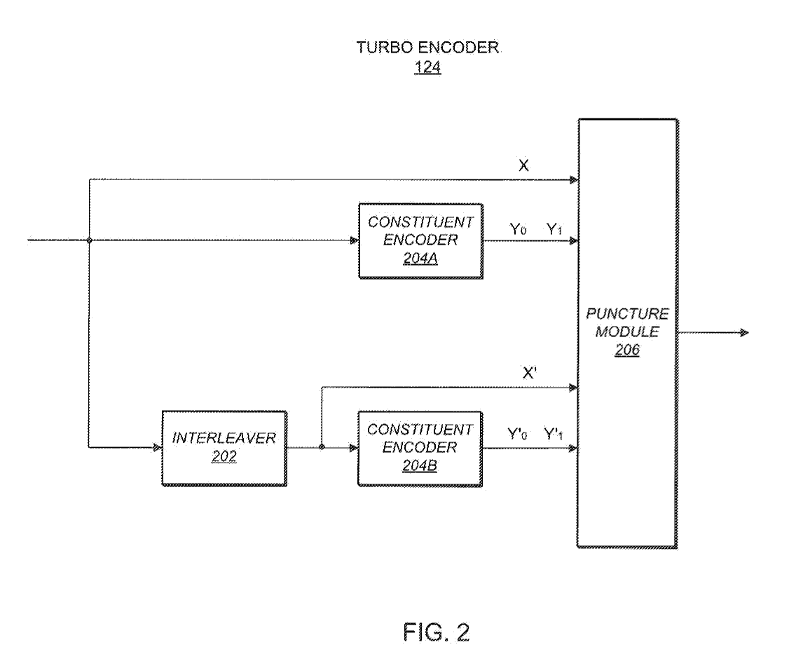

FIG. 2 is a schematic block diagram illustrating an example of a turbo encoder. The turbo encoder 108 includes two constituent encoders 204A, 204B operated in parallel and in combination with an interleaver 202. The interleaver 202 rearranges (i.e., interleaves) the data (or tail) bits in the code segment in accordance with a defined interleaving scheme. One constituent encoder 204A encodes the bits in the code segment to generate two sequences of parity bits (Y₀ and Y₁), and the other constituent encoder 204B encodes the interleaved bits to generate another two sequences of parity bits (Y₀ and Y₁). The original and interleaved bit streams are provided to the input of a puncture module 206, along with the parity symbols output from two constituent encoder 204A, 204B. The puncturing module 206 converts six parallel code symbol (X, X′,Y₀, Y₁, Y′₀, Y′₁) into a serial output each bit period. The puncture module 206 may also be used to puncture (not transmit) the interlaced systematic symbols (X′) and/or one or more of the parity symbols (Y₀, Y₁, Y′₀, Y′₁) each bit period to achieve the desired code rate.

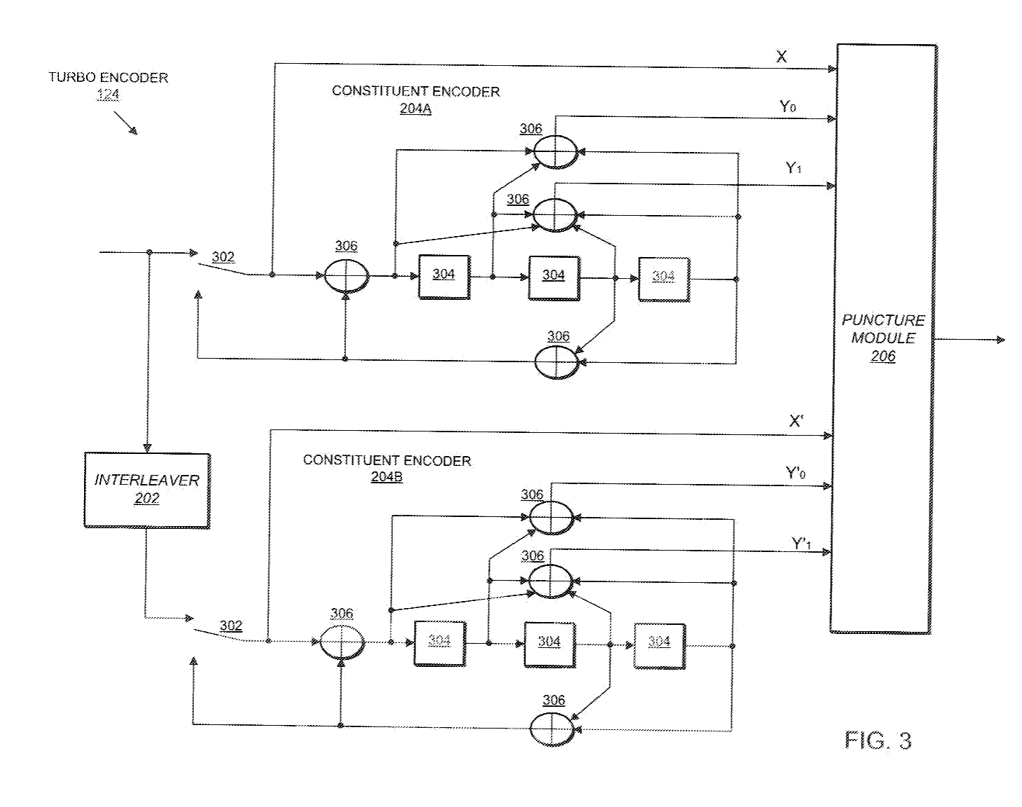

FIG. 3 is a schematic block diagram depicting the turbo encoder of FIG. 2 in greater detail. The turbo encoder 108 is shown with the two constituent encoders 204A, 204B connected in parallel, and separated by the interleaver 202 as described with reference to FIG. 2. The constituent encoders 204a, 204b are systematic, recursive convolutional encoders. The two recursive convolutional codes generated by the encoders 204A, 204B are called the constituent codes of the turbo code. The original and interleaved bit streams, along with the constituent codes, are punctured by the puncturing module 206 to achieve the desired code rate.

Each constituent encoder 204A, 204B includes a switch 302 and a number of registers 304 and adders 306. The registers 304 in each of the encoders 204A, 204B are initially set to zero. The constituent encoders 204A, 204B are then clocked once for each bit period with the switch up. Next, the tail is generated by clocking one of the constituent encoders 204A for three bit periods with the switch 302 down and then clocking the other constituent encoder 204B for three bit periods with its switch 302 down.

An example of puncturing algorithms code symbols derived from the data and tail bits is illustrated in Tables 1 and 2 below. Those skilled in the art will readily understand that other puncturing algorithms may be used depending on the particular application and the overall design constraints imposed on the system.

The code symbols for the data bits may be punctured as shown in Table 1 below.

TABLE 1
Puncturing Pattern for Bit periods

Code Rate

| Output | 1/5 | 1/3 | 1/2 | 2/3 |
|---|---|---|---|---|
| X | 1 | 11 | 11 | 1111 |
| Y₀ | 1 | 11 | 10 | 1000 |
| Y₁ | 1 | 00 | 00 | 0000 |
| X′ | 0 | 00 | 00 | 0000 |
| Y′₀ | 1 | 11 | 01 | 0001 |
| Y′₁ | 1 | 00 | 00 | 0000 |

The puncturing table is read first from top to bottom and then from left to right.

Within a puncturing pattern, “0” means that the symbol is punctured (deleted) and “1” means that the symbol is output from the turbo encoder 108. Each column represents the code symbols output from the turbo encoder 108 during a bit period. Referring to Table 1, code symbols X, Y₀, Y′₀, Y₁, and Y′₁ are output from the turbo encoder 108 every bit period when the code rate is ⅕. When the code rate is ⅓, code symbols X, Y₀ and Y′₀ are output from the turbo encoder 108 every bit period. When the code rate is ½, code symbols X and Y₀ are output from the turbo encoder 108 during a first bit period, followed by symbols X and Y′₀ during the next bit period. When the code rate is ⅔, code symbols X and Y₀ are output from the turbo encoder 108 during a first bit period, followed code symbol X in each of the next two bit periods, followed by code symbols X and Y′₀ in the next bit period when the code rate is ⅔.

The tail symbols may be punctured as shown in Table 2 below.

TABLE 2
Puncturing Pattern for Tail Symbols

Code Rate

| Output | 1/5 | 1/3 | 1/2 | 2/3 |
|---|---|---|---|---|
| X | 222 000 | 222 000 | 111 000 | 111 000 |
| Y₀ | 111 000 | 111 000 | 111 000 | 101 000 |
| Y₁ | 222 000 | 000 000 | 000 000 | 000 000 |
| X′ | 000 222 | 000 222 | 000 111 | 000 111 |
| Y′₀ | 000 111 | 000 111 | 000 111 | 000 010 |
| Y′₁ | 000 222 | 000 000 | 000 000 | 000 000 |

The puncturing table is read first from top to bottom and then from left to right.

Within a puncturing pattern, “0” means that a tail symbol is deleted, “1” means that a tail symbol is passed and “2” means that a tail symbol is passed twice. Each column represents the tail symbols output from the turbo encoder 108 during a bit period. Referring to Table 2, the tail symbols for each of the first three bit periods is XXY₀Y₁Y₁, and the tail symbols for each of the last three bit periods is X′X′Y′₀Y′₁Y′₁ when the code rate is ⅕. When the code rate is ⅓, the tail symbols for each of the first three bit periods is XXY₀, and the tail symbols for each of the last three bit periods is X′X′Y′₀. When the code rate is ½, the tail symbols output from the turbo encoder 108 for each of the first three bit periods is XY₀ , and the tail symbols output from the turbo encoder 108 for each of the last three bit periods is X′Y′₀. When the code rate is ⅔, the tail symbols for the first three bit periods are XY₀, X, and XY₀, respectively and the tail symbols for the last three bit periods are X′, X′Y′₀, and X′, respectively.

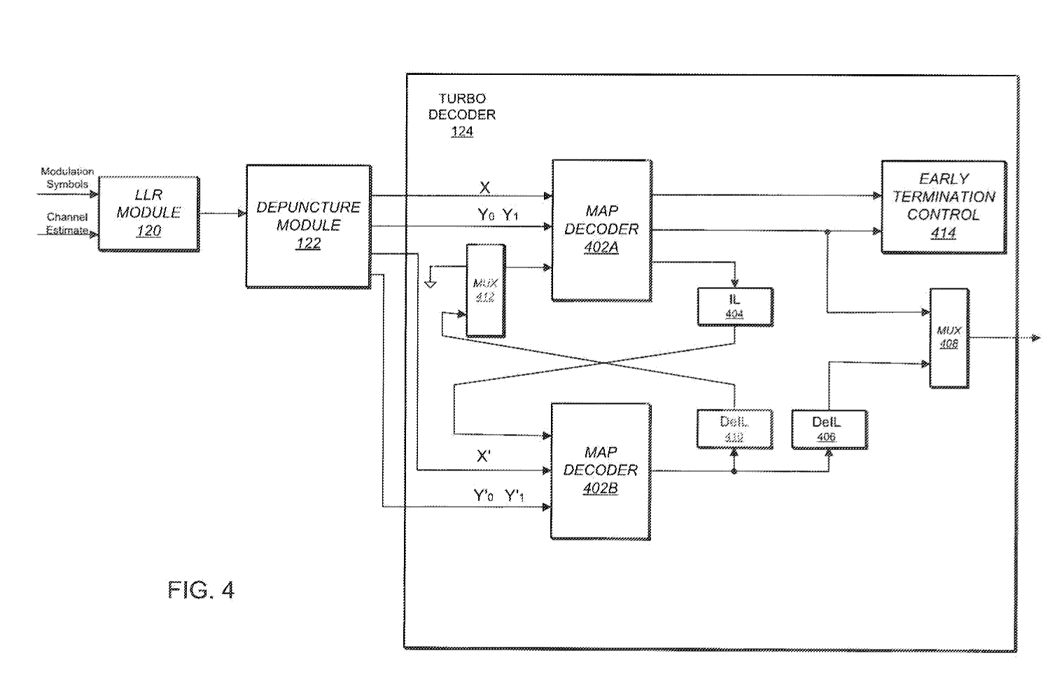

FIG. 4 is a schematic block diagram depicting the receiver of FIG. 1 with greater detail for the turbo decoder 124. As mentioned above, the soft decisions from demodulator 116 are used by the LLR module 120 to determine the LLR values of the code symbols. An LLR value is the logarithm of the likelihood ratio. The likelihood ratio can be defined as the probability that the transmitted code symbol is “1” over the probability that it is to “0”. Alternatively, the likelihood ratio can be defined in a reverse way, where the likelihood ratio is the probability that the transmitted code symbol is “0” over the probability that it is “1”.

The LLR module 120 utilizes a channel estimate and the soft decision from the demodulator 116 to determine a LLR value. A noise estimate may also be used. However, the noise estimate term can be substantially ignored if the turbo decoding method provides the same results regardless of whether a noise estimate is used. In such an configuration, the LLR module 120 can use a predetermined value as the noise estimate in calculating LLR values.

The LLR values generated by the LLR module 120 are provided to the turbo decoder 124 by a depuncture module 122. As will be explained in greater detail later, the depuncture module 122 provides a means for enabling the turbo decoder to selectively operate at a symmetric code rate and an asymmetric code rate. Turning to the turbo decoder 124, there are two constituent decoders 402A, 402B shown in FIG. 4. Each constituent decoder 402A, 402B may be implemented as a maximum a posteriori (MAP) decoder that generates a priori probability (APP). The APP represents the likelihood that a systematic symbol input to the MAP decoder is either a “0” or a “1”. The first MAP decoder 402A calculates a sequence of APP values from the LLR values for the systematic and parity symbols (X, Y₀, Y₁) in a code segment during a first pass through the turbo decoder 124. The APP values calculated by the first MAP decoder 402A are rearranged by an interleaver 404 to match the interleaving used by the turbo encoder 108 in the transmitter 104 (see FIG. 2). The interleaved APP values are then provided to the second MAP decoder 402B, along with the LLR values for the parity symbols (X Y′₀, Y′₁) from the code segment. The second MAP decoder 402B generates a sequence of decoded bits (i.e., hard decisions) during a second pass through the turbo decoder 124. The bit sequence is deinterleaved by a deinterleaver 406 and provided to the output of the turbo decoder 124 through a multiplexer 408.

Two passes through the turbo decoder 124 constitutes one iteration. Multiple iterations through the turbo decoder 124 may be required to generate bits with a low bit-error ratio (BER). The iterative process gradually corrects errors, and given enough iterations and a high enough signal to noise ratio (SNR), all the errors can be corrected.

A second iteration may be accomplished using a sequence of APP values generated by the second MAP decoder 402B during the first iteration. The sequence of APP values are deinterleaved by a deinterleaver 410 and fed back to the first MAP decoder 402A through a multiplexer 412. During the first iteration, the APP input to the first MAP decoder 402A is grounded. The first MAP decoder 402A calculates a new sequence of APP values from the LLR values for the code symbols (X, Y₀, Y₁) and the deinterleaved APP values from the second MAP decoder 402B. The new APP values are interleaved and provided to the second MAP decoder 402B, along with the code symbols (X′, Y′₀, Y′₁). The second MAP decoder 402B generates a new sequence of decoded bits and APP values. If a third iteration is to be performed, the new APP values can be once again deinterleaved and fed back to the first MAP decoder 402A. Otherwise, the decoded bit sequence is output from the turbo decoder 124.

Ideally in high SNR cases, each set of APP values is better than the preceding set, so that hard decisions are made with a greater degree of confidence after each iteration. The actual number of iterations for any particular application may be fixed, or alternatively, determined on the fly to meet the minimum quality of service requirements. An early termination control module 414 may be used to terminate the turbo decoding process early when the hard decisions, for example, surpass a minimal threshold test. The turbo decoding process may be terminated at the end of an iteration or in the middle of one. In the latter case, the first MAP decoder 402A generates a sequence of decoded bits and provides the decoded bits to the output of the turbo decoder 124 through the multiplexer 408.

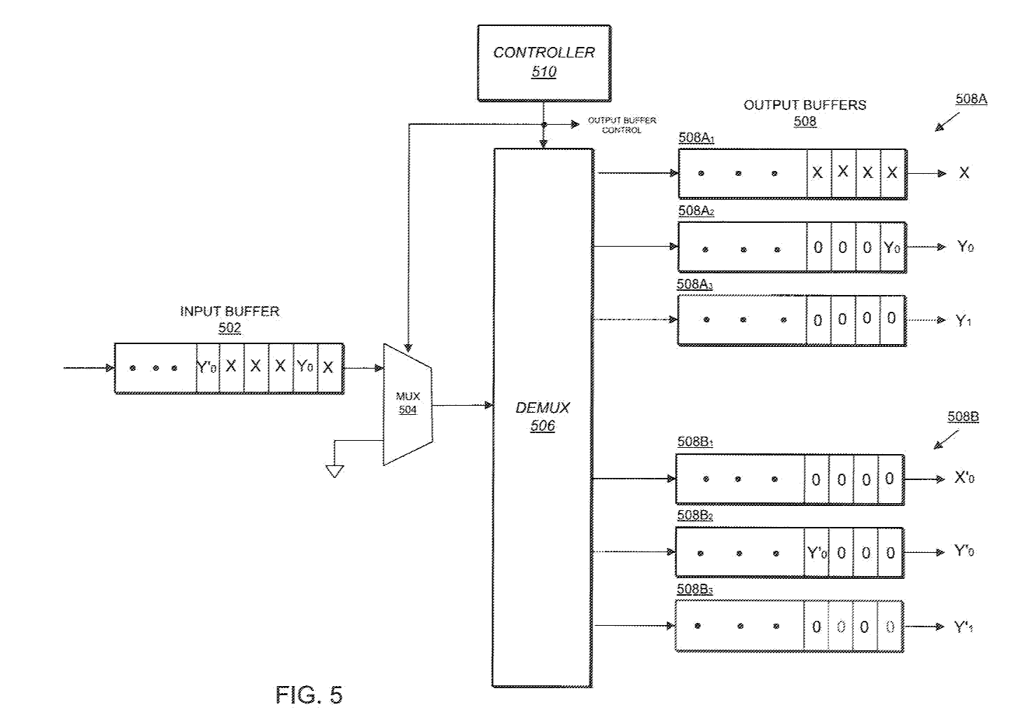

FIG. 5 is a conceptual diagram illustrating an example of the depuncture module 122. Conceptually, the depuncture module 122 includes an input buffer 502 that receives and stores the LLR values for the code symbols of a code segment. The depuncture module 122 also includes two sets of output buffers 508A, 508B. The first set of output buffers 508A is used to provide the LLR values for the code symbols (X, Y₀, Y₁) to the first MAP decoder 402A and the second set of output buffers 508B is used to provide the LLR values for the code symbols (X′, Y′₀, Y′₁)to the second MAP decoder 402B (see FIG. 4). The first set of output buffers 508A includes a buffer 508A₁ to store the LLR values for the systematic symbol (X), and buffers 508A₂, 508A₃ to store the LLR values for the parity symbols (Y₀, Y₁), respectively. The second set of output buffers 508B includes a buffer 508B₁ to store the LLR values for the systematic symbol (X′), and buffers 508B₂, 508B₃ to store the LLR values for the parity symbols (Y′₀, Y′₁), respectively.

A multiplexer 504 is used to provide LLR values for unused code symbols in the selected rate. By way of example, code symbols Y₁, X′, and Y′₁ are not used when the code rate is ⅔ (see Table 1). In this example, these LLR values are set to “0” through the multiplexer 504. Stated differently, the LLR values from the input buffer 502 are depunctured with zeros to accommodate the selected code rate. Alternatively, the LLR values from the input buffer 502 may be depunctured with other information that indicates that a particular code symbol in a particular bit period is not available for the selected code rate. The punctured LLR values are transferred to the appropriate output buffers 508 by a demultiplexer 506.

A controller 510 enables the turbo decoder 124 to support multiple code rates by controlling the manner in which the output buffers 506 are filled with the punctured LLR values. Specifically, the controller 510 is configured to control the multiplexer 504 and demultiplexer 506 to fill the output buffers 506 differently for each code rate. The controller 510 also controls the output buffers 508 by releasing the LLR values from the first set of output buffers 508a when the first MAP decoder 402a in the turbo decoder 124 is operating and the LLR values from the second set of output buffers 508b when the second MAP decoder 402b in the turbo decoder 124 is operating (see FIG. 4).

An example of a process performed by the depuncture module 122 for a ⅔ code rate will now be described with reference to FIG. 5. In this example, the input buffer 502 receives LLR values for a systematic symbol X and a parity symbol Y₀ in the first bit period, followed by a systematic code symbol X in each of the next two bit periods, followed by a systematic code symbol X and a parity symbol Y′₀ in the next bit period. This process repeats until all the LLR values for all the data bit code symbols bits in the code segment are received by the input buffer 502.

Although not shown, the input buffer 502 also receives the LLR values for tail symbols at the end of the code segment (i.e., the last six bit periods). The LLR values for the tail symbols for the first three bit periods of the tail are XY₀, X, and XY₀, respectively, and the tail symbols for the last three bit periods of the tail are X′, X′Y′₀, and X′, respectively.

Once the input buffer 502 is full, or at some time prior, the LLR values from the input buffer 502 are transferred to the output buffers.508 The LLR values for the systematic symbol X and parity symbol Y₀ for the first bit period are transferred from the input buffer 502 to the output buffers 508A₁, 508A₂, respectively, with zeros being loaded into the output buffers 508A₃, 508B₁, 508B₂, 508B₃. Next, the LLR values for the systematic symbol X for the second bit period is transferred from the input buffer 502 to the output buffer 508a₁ and zeros are loaded into the other output buffers 508A₂, 508A₃, 508B₁, 508B₂, 508B₃. Then, the LLR values for the systematic symbol X for the third bit period is transferred from the input buffer 502 to the output buffer 508A₁ and zeros are loaded into in the other output buffers 508A₂, 508A₃, 508B₁, 508B₂, 508B₃. After that, the LLR values for the systematic symbol X and parity Y′₀ for the fourth bit period are transferred from the input buffer 502 to the output buffers 508A₁, 508B₂, respectively, and zeros are loaded into the output buffers 508A₂, 508A₃, 508B₁, 508B₃. This process repeats until the LLR values for all the data bit code symbols in the code segment are transferred from the input buffer 502 to the output buffers 508.

Although not shown, the LLR values for tail symbols in the six bit periods at the end of the code segment are transferred to the output buffers 508 next. The LLR values for the systematic symbol X and parity symbol Y₀ for the first bit period of the tail are transferred from the input buffer 502 to the output buffers 508A₁, 508A₂, respectively, and zeros are loaded into the output buffers 508A₃, 508B₁, 508B₂, 508B₃. Next, the LLR value for the systematic symbol X for the second bit period of the tail is transferred from the input buffer 502 to the output buffer 508A₁ and zeros are loaded into the output buffers, 508A₂, 508A₃, 508B₁, 508B₂, 508B₃. Then, the LLR values for the systematic symbol X and parity symbol Y₀ for the third bit period of the tail are transferred from the input buffer 502 to the output buffers 508A₁, 508A₂, respectively, and zeros are loaded into the output buffers 508A₃, 508B₁, 508B₂, 508B₃. After that, the LLR value for the systematic symbol X′ for the fourth bit period of the tail is transferred from the input buffer 502 to the output buffer 508B₁, and zeros are loaded into the output buffers 508A₁, 508A₂, 508A₃, 508B₂, 508B₃. Next, the LLR value the systematic symbol X′ and parity symbol Y′₀ for the fifth bit period of the tail are transferred from the input buffer 502 to the output buffer 508B₁, 508B₂, and zeros are loaded into the output buffers 508A₁, 508A₂, 508A₃, 508B₃. Finally, the LLR value for the systematic symbol X′ for the last bit period of the tail is transferred from the input buffer 502 to the output buffer 508B₁, and zeros are loaded into the output buffers 508A₁, 508A₂, 508A₃, 508B₂, 508B₃.

Referring to FIGS. 4 and 5, the LLR values are released from the first set of output buffers 508a during the operation of the first MAP decoder 402a in the turbo decoder 124. During the first bit period, the LLR values for the systematic symbol X and parity symbol Y₀ are released from the output buffers 508A₁, 508A₂, respectively, along with a zero from the output buffer 508A₃. During each of the next three bit periods, the LLR value for the systematic symbol X is released from the output buffer 508A₁, along with zeros from each of the output buffers 508A₂, 508A₃. This process continues until the all the LLR values for the data bit code symbols have been released from the output buffers 508A₁, 508A₂, 508A₃ and processed by the first MAP decoder 402A in the turbo decoder 124.

The first MAP decoder 402A is then reinitialized for the tail symbols. Although not shown, the LLR values for the tail symbols are then released from the first set of output buffers 508. During the first bit period of the tail, the LLR values for the systematic symbol X and parity symbol Y₀ are released from the output buffers 508A₁, 508A₂, respectively, along with a zero from the output buffer 508A₃. During the second bit period of the tail, the LLR value for the systematic symbol X is released from the output buffer 508A₁, along with zeros from the output buffers 508A₂, 508A₃. During the third bit period of the tail, the LLR values for the systematic symbol X and parity symbol Y₀ are released from the output buffers 508A₁, 508A₂, respectively, along with a zero from the output buffer 508A₃.

Once the code symbols from the first set of output buffers 508a are processed by the first MAP decoder 402A, the resultant APP values are interleaved and stored in the depuncture module 122, or elsewhere, for use during the operation of the second MAP decoder 402b.

The LLR values are released from the second set of output buffers 508B during the operation of the second MAP decoder 402A. During each of the first three bit periods, zeros are released from each of the output buffers 508B₁, 508B₂, 508B₃. For each of these three bit periods, the zeros are processed by the second MAP decoder 402B, along with the corresponding APP values from the first MAP decoder 40Aa. During the fourth bit period, the LLR value for the parity symbol Y′₀ is released from the output buffer 508B₂, along with zeros from the output buffers 508B₁, 508B₃. The LLR value for the parity symbol Y′₀, and the zeros are processed by the second MAP decoder 402B, along with the corresponding APP value from the first MAP decoder 402A. This process continues until all the LLR values for the data bit code symbols have been released from the output buffers 508B₁, 508B₂, 508B₃ and processed by the second MAP decoder 402B.

The second MAP decoder 402B is then reinitialized for the tail symbols. Although not shown, the LLR values for the remaining tail symbols in the second output registers 508B are released. During the first bit period of the tail, the LLR value for the systematic symbol X′ is released from the output buffer 508B₁, along with zeros from the output buffers 508B₂, 508B₃. Next, during the second bit period of the tail, the LLR values for the systematic symbol X′, and parity symbol Y′₀ are released from the output buffers 508B_{1 508B}₂, respectively, along with a zero from the output buffer 508B₃. Then, during the third bit period, the LLR values for the systematic symbol X′ is released from the output buffers 508B₁, along with zeros from the output buffers 508B₂, 508B₃.

Once the code symbols from the second set of output buffers 508B are processed by the second MAP decoder 402A, the resultant APP values may be deinterleaved and stored in the depuncture module 122, or elsewhere, if another iteration is to be performed.

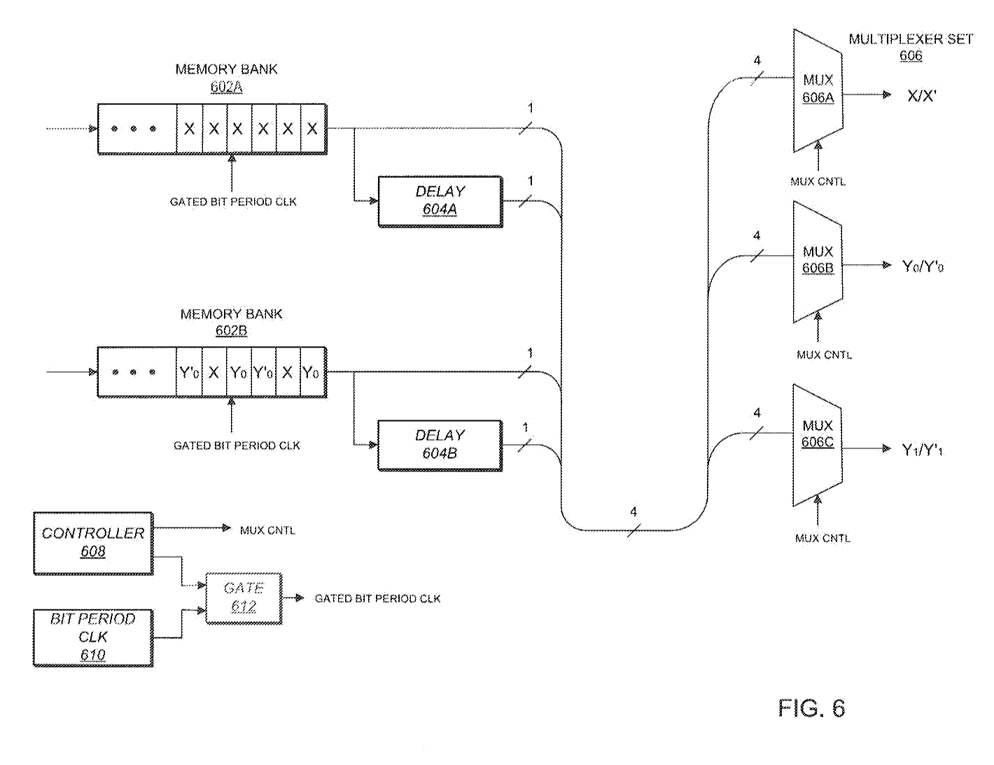

The hardware implementation of the depuncture module 122 may be significantly different from the conceptual configuration described above in connection with FIG. 5. By way of example, the depuncture module 122 may need to support a turbo decoder 124 that implements the first and second MAP decoders with a single MAP decoder. An example of a hardware implementation of a depuntcure module 122 capable of supporting this turbo decoder configuration is shown in FIG. 6. In this example, two memory banks 602A, 602B are used to receive and store the LLR values for the code symbols. Two delays 604A, 604B are used to make code symbols from two consecutive bit periods in each memory bank 602A, 602B available to a set of multiplexers 606. The delays may be D latches or any other component capable of delaying the output of a memory bank by one bit period. The multiplexer set 606 includes a first multiplexer 606a to provide the systematic symbols X, X′ to the turbo decoder 124, a second multiplexer 606b to provide the parity symbols Y₀,Y′₀ to the turbo decoder 124, and a third multiplexer 606c to provide the parity symbols Y₁, Y′₁ to the turbo decoder 124. A controller 608 is used to control the multiplexer set 606 based on the selected code rate. The controller also controls the pointer to the memory banks 606A, 606B, which is reset after each pass through the turbo decoder (i.e., ½ iteration).

The use of the delays 604A, 604B provides a means for supporting both symmetric and asymmetric code rates. As can be seen from FIG. 6, two systematic symbols can occupy the same pointer position in the two memory banks 606A, 606B. Although not shown, this same condition exists for the tail. This condition is unique to asymmetric code rates, such as the ⅔ code rate described in this example. Thus, the first multiplexer 606a can release the systematic symbol X from the second pointer position from the first memory bank 602A during the second bit period and release the systematic symbol X output from the delay 604B from the second memory bank 602B during the next bit period.

Alternatively, asymmetric code rates can be handled with a gated clock. In this example, a bit period clock is used to clock the LLR values through the first and second memory banks 602A, 602B. The bit period clock is also used to clock the delays 604A, 604B. The bit period clock may be the system clock or a divided down version of the system clock. A gate 612 is used to gate off the data bit clock when the pointer position is to a systematic symbol in both the first and second memory banks 602A, 602B. By gating off the bit period clock, the systematic symbols at the pointer position remain available for two consecutive bit periods. As a result, the systematic symbol from the first memory bank 602A can be output from the multiplexer 606A during one bit period and the systematic symbol from the second memory bank 602B can be output from the same multiplexer 606A during the next bit period.

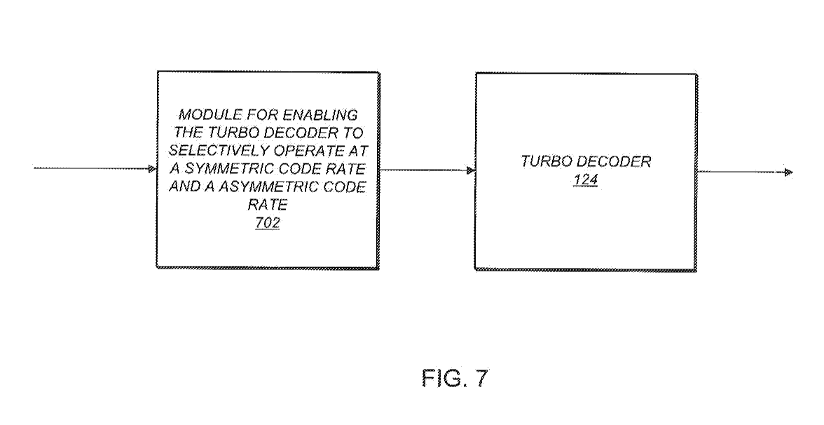

FIG. 7 is a functional block diagram illustrating a portion of a receiver. 106, the receiver is shown with a turbo decoder 124 and a module 702 for enabling the turbo decoder to selectively operate at a symmetric code rate and an asymmetric code rate.

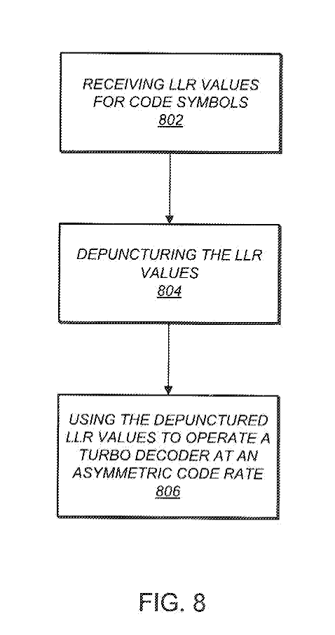

FIG. 8 is a flow diagram illustrating an example of a method of communications using a turbo decoder capable of operating at symmetric and asymmetric code rate. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence.

In step 802, a LLR values for code symbols are received from a LLR module. The code symbols may be derived from data and tail bits. In step 804, the LLR values are depunctured to enable a turbo decoder to operate at an asymmetric code rate. An example of an asymmetric code rate is ⅔. In step 804, the depunctured LLR values are used to operate the turbo decoder at the asymmetric code rate.

The turbo decoder may include a MAP decoder having a systematic input, and first and second parity inputs. In this configuration of a turbo decoder, the LLR values are depunctured to support the inputs of the MAP decoder.

The turbo decoder may be configured to perform an iteration comprising two passes through the MAP decoder. In this configuration, the received LLR values include a first set of LLR values derived from a bit stream and a second set of LLR values derived from an interlace of the bit stream. The depunctured LLR values from the first set are provided to the MAP decoder during the first pass, and the depunctured LLR values from the second set are provided to the MAP decoder during the second pass.

The LLR values may be depunctured using a hardware configuration with first and second memory banks. The LLR values received from the LLR module may be alternatively stored between the first and second memory banks. The outputs from each memory bank may be delayed, and the outputs and delayed outputs from the memory banks used to multiplex the LLR values to provide depunctured LLR values to the turbo decoder.

The previous description is provided to enable any person skilled in the art to practice the various embodiments described herein. Various modifications to these embodiments will be readily apparent to those skilled in the art, and the generic principles defined herein may be applied to other embodiments. Thus, the claims are not intended to be limited to the embodiments shown herein, but is to be accorded the full scope consistent with the language claims, wherein reference to an element in the singular is not intended to mean “one and only one” unless specifically so stated, but rather “one or more.” All structural and functional equivalents to the elements of the various embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A receiver, comprising:
a turbo decoder; and
a depuncture module configured to enable the turbo decoder to selectively operate at a symmetric code rate and an asymmetric code rate.

2. The receiver of claim 1 wherein the asymmetric code rate is ⅔.

3. The receiver of claim 1 further comprising a LLR module configured to provide LLR values to the depuncture module, wherein the depuncture module is further configured to depuncture the LLR values in accordance with the selected code rate and provide the depunctured LLR values to the turbo decoder.

4. The receiver of claim 3 wherein the turbo decoder includes a MAP decoder having a systematic input, and first and second parity inputs, and wherein the depuncture module is further configured to depunctured the LLR values to support the inputs to the MAP decoder at each of the code rates.

5. The receiver of claim 4 wherein the turbo decoder is configured to perform an iteration comprising two passes through the MAP decoder, wherein the LLR values provided to the depuncture module includes a first set of LLR values derived from a bit stream and a second set of LLR values derived from an interlace of the bit stream, the depuncture module being further configured to provide the depunctured LLR values from the first set to the inputs of the MAP decoder during the first pass, and provide the depunctured LLR values from the second set during the second pass.

6. The receiver of claim 4 wherein the depuncture module comprises first and second memory banks configured to buffer the LLR values from the LLR module.

7. The receiver of claim 6 wherein the depuncture module is further configured to alternatively store the LLR values received from the LLR module between the first and second memory banks.

8. The receiver of claim 6 wherein each of the first and second memory banks includes a pointer configured to be moved every data bit period, and wherein the depuncture module is further configured to selectively hold the pointer at the same location for two consecutive data bit periods to support the asymmetric code rate.

9. The receiver of claim 6 further comprising a first delay at the output of the first memory bank, second delay at the output of the second memory bank, and three multiplexers, one of the multiplexers being configured to provide the LLR values for the systematic symbols to the turbo decoder, and the other multiplexers being configured to provide the LLR values for the parity symbols to the turbo decoder, and wherein each of the multiplexers has available to it the LLR values output from the first and second memory banks and the first and second delays.

10. The receiver of claim 3 wherein the depuncture module is further configured to provide LLR values for code symbols derived from data and tail bits.

11. A receiver, comprising:
a turbo decoder; and
means for enabling the turbo decoder to selectively operate at a symmetric code rate and an asymmetric code rate.

12. The receiver of claim 11 wherein the asymmetric code rate is ⅔.

13. The receiver of claim 11 wherein the turbo encoder enabling means comprises means for depuncturing LLR values in accordance with the selected code rate and means for providing the depunctured LLR values to the turbo decoder.

14. The receiver of claim 13 wherein the turbo decoder includes a MAP decoder having a systematic input, and first and second parity inputs, and wherein the means for depuncturing the LLR values is configured to depuncture such LLR values to support the inputs to the MAP decoder at each of the code rates.

15. The receiver of claim 14 wherein the turbo decoder is configured to perform an iteration comprising two passes through the MAP decoder, wherein the LLR values provided to the turbo decoder enabling means includes a first set of LLR values derived from a bit stream and a second set of LLR values derived from an interlace of the bit stream, and wherein the means for providing the depunctured LLR values to the turbo decoder is configured to provide the depunctured LLR values from the first set to the inputs of the MAP decoder during the first pass, and provide the depunctured LLR values from the second set during the second pass.

16. The receiver of claim 13 wherein the means for providing the depunctured LLR values to the turbo decoder is configured to provide LLR values for code symbols and tail symbols at each of the code rates.

17. A method of communications using a turbo decoder capable of operating at a symmetric code rate, comprising:
depuncturing LLR values for code symbols to enable the turbo decoder to operate at an asymmetric code rate; and
using the depunctured LLR values to operate the turbo decoder at the asymmetric code rate.

18. The method of claim 17 wherein the asymmetric code rate is ⅔.

19. The method of claim 17 wherein the turbo decoder includes a MAP decoder having a systematic input, and first and second parity inputs, and wherein the LLR values are depunctured to support the inputs of the MAP decoder.

20. The method of claim 19 wherein the turbo decoder is configured to perform an iteration comprising two passes through the MAP decoder, the method further comprising receiving the LLR values, the LLR values including a first set of LLR values derived from a bit stream and a second set of LLR values derived from an interlace of the bit stream, and wherein the method further comprises providing the depunctured LLR values from the first set to the MAP decoder during the first pass, and providing the depunctured LLR values from the second set to the MAP decoder during the second pass.

21. The method of claim 17 wherein the depuncturing of LLR values comprises receiving the LLR values and storing the received LLR values in first and second memory banks.

22. The method of claim 21 wherein the received LLR values are alternatively stored between first and second memory banks.

23. The method of claim 21 wherein each of the first and second memory banks having a pointer configured to be moved every bit period, and wherein the depuncturing of LLR values further comprises selectively holding the pointer at the same location for two consecutive data bit periods to support the asymmetric code rate.

24. The method of claim 21 wherein the depuncturing of the LLR values further comprises delaying the outputs of the first and second memory banks, and multiplexing the outputs and the delayed outputs from the first and second memory banks.

25. The method of claim 17 wherein the code symbols derived from data and tail bits.
